(19) United States
(12) Patent Application Publication
(10) Pub. No.: US 2002/0031154 A1
(43) Pub. Date: Mar. 14, 2002

(54) Surface emitting semiconductor laser device

(76) Inventors: Noriyuki Yokouchi, Tokyo (JP); Akihiko Kasukawa, Tokyo (JP)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/905,194

(22) Filed: Jul. 13, 2001

Related U.S. Application Data
(63) Continuation of application No. PCT/JP00/08047, filed on Nov. 15, 2000.

(30) Foreign Application Priority Data
Nov. 16, 1999 (JP) 11-326021

(51) Int. Cl. H01S 3/08; H01S 5/00

(52) U.S. Cl. 372/46; 372/96

(57) ABSTRACT

A surface emitting semiconductor laser device has a layered structure of semiconductor materials formed on a substrate 1. The layered structure has an upper reflector layered structure (5), a lower reflector layered structure (2), and a light-emitting layer (4) interposed therebetween. A current injection path (3e) is formed in close proximity to the light-emitting layer (4). An upper electrical contact (7a), which is annular in plan configuration, is formed on the upper surface of the upper reflector layered structure (5). The outside of the upper electrical contact (7a) is coated with a dielectric film (8) and a metallic film (9). The metallic film (9) is formed being in contact with the upper electrical contact (7a), and the inside of the upper electrical contact (7a) serves as a laser light emission window. The peripheral rim portion (6c) of the emission window is coated with the metallic film (9) to define the aperture diameter of the emission window (6A) by the metallic film (9), thereby controlling the lateral lasing mode of laser light. The aperture diameter (D₀) of the emission window (6A) is made smaller than the aperture diameter (D₁) of the current injection path (3e) and the aperture diameter (D₁) of the current injection path is greater than 10 micrometers.

CROSS REFERENCE TO RELATED APPLICATION

This application is a continuation of and claims priority to PCT application number PCT/JP00/08047, filed on Nov. 15, 2000.

### TECHNICAL FIELD

The present invention relates to surface emitting semiconductor laser devices. More particularly, it relates to a surface emitting semiconductor laser device which can accurately control the lateral lasing mode in a simple arrangement and realize the fundamental lateral lasing mode at a low operating voltage.

### BACKGROUND ART

Today, research on the development of large-capacity optical communication networks has been conducted as well as on the development of optical data communication systems such as for optical interconnections or optical computing. Meanwhile, attention has focused on surface emitting semiconductor laser devices, which emit the laser light in the direction perpendicular to the substrate, as the light source of these communication networks or communication systems.

An example of basic layered structures of such surface emitting semiconductor laser devices is shown in FIG. 11.

The laser device A shown in Fig. 11 comprises a layered structure formed on a substrate 1. The layered structure includes a lower reflector layered structure 2, a lower cladding layer 3a, an active layer (hereinafter may also be referred to as the light-emitting layer) 4, an upper cladding layer 3b, an upper reflector layered structure 5, and a layer 6. Accordingly, the entire layered structure is formed to be perpendicular to the substrate surface, constituting a resonator for emitting the laser light in a vertical direction.

More specifically, a laser device A has the substrate 1 of, for example, n-type GaAs surmounted by the lower reflector layered structure 2 of alternating thin layers of different compositions of, for example, n-type AlGaAs. In addition, for example, the lower cladding layer 3a of i-type AlGaAs, the light-emitting layer 4 comprising a quantum well structure of GaAs/AlGaAs, and the upper cladding layer 3b of i-type AlGaAs are deposited on the lower reflector layered structure 2, in that order. Moreover, on the upper cladding layer 3b, formed is the upper reflector layered structure 5 of alternating thin layers of different compositions of, for example, p-type AlGaAs. The layer 6 of p-type GaAs is formed on the surface of the uppermost layer of the upper reflector layered structure 5. Furthermore, in the layered structure from the lower reflector layered structure 2 to the GaAs layer 6, the portion from the GaAs layer 6 to the upper surface of the lower reflector layered structure 2 is formed to be cylindrical in shape by etching.

In addition, there is formed an annular upper electrical contact 7a of, for example, AuZn on the peripheral rim portion of the upper surface of the GaAs layer 6. Moreover, there is formed a lower electrical contact 7b of, for example, AuGeNi/Au on the reverse surface of the substrate 1.

Moreover, the peripheral surface 5a of the cylindrical layered structure, the upper surface of the peripheral rim portion 6b of the GaAs layer 6, and the upper surface of the lower reflector layered structure 2 are coated, for example, with a dielectric film 8 of SiNx. The center portion 6a of the GaAs layer 6 is arranged radially inwardly of the upper electrical contact 7a and is thus not coated with the dielectric film 8 to constitute a laser light emission window. Furthermore, for example, the surfaces of the upper electrical contact 7a and the dielectric film 8 are coated with a metallic film pad 9 of Ti/Pt/Au for use as an electrical contact lead.

Furthermore, a lowermost layer 3c of the upper reflector layered structure 5 is located in the closest proximity to the light-emitting layer 4 and is formed of, for example, p-type AlAs.

In addition, the peripheral rim portion of the lowermost layer 3c is subjected to oxidation to allow only the AlAs of the layer 3c to be selectively oxidized, thereby forming an insulated region 3d having an annular shape in plan configuration and composed mainly of Al₂O₃. The center portion of the lowermost layer 3c is composed of non-oxidized AlAs and constitutes a current injection path 3e. As described above, the lowermost layer 3c constitutes, as a whole, a structure for confining current to the light-emitting layer 4.

The laser device A configured as described above is adapted to generate lasing in the light-emitting layer 4 by applying a voltage between the upper electrical contact 7a and the lower electrical contact 7b. Then, laser light is adapted to be emitted upwardly outwardly in the direction perpendicular to the substrate 1, as shown by an arrow, through the emission window 6a provided on the GaAs layer 6.

However, it is necessary to control the lateral lasing mode of the laser light emitted from the laser device in order to incorporate the surface emitting semiconductor laser device into an optical transmission system as the light source thereof.

An inter-board optical transmission system, to which free-space propagation is applied, and a high-speed optical transmission system with single mode optical fibers require a laser device, as the light source thereof, to provide a fundamental lateral lasing mode.

Conventionally, the dimensions of the current confinement structure shown in FIG. 11 are varied to control the lateral lasing mode of the surface emitting semiconductor laser device. More specifically, the annular insulated region 3d constituting the peripheral rim portion of the lowermost layer 3c of the upper reflector layered structure 5 is varied in width. The circular current injection path 3e located at the center portion of the layer 3c is thus varied in diameter, thereby controlling the lateral lasing mode of the laser device.

For example, in the case where a laser device that lases in the fundamental lateral mode, it is required to reduce the diameter of the current injection path 3e to approximately five micrometers or less. However, reducing the diameter of the current injection path 3e would cause the resistance of the laser device to increase, thereby leading to a disadvantageous increase in operating voltage of the laser device.

Thus, the current injection path 3e has to be controlled with accuracy on the order of a micrometer in diameter. For this purpose, it is necessary to control with accuracy the width of the insulated region 3d, or the oxidization width of the AlAs layer 3c. However, it is difficult to control the oxidation width on the order of a micrometer. For this reason, laser devices to be controlled in diameter of the current injection path during their fabrication are prone to variations in property, thereby turning into a problem of reproducibility. Incidentally, suppressing of part of higher order lateral lasing modes by controlling the current injection path in diameter would allow a filtering effect to be expected.

It has been reported that it is effective in control of the fundamental lateral lasing mode to coat the uppermost surface of a laser device configured in a current confinement structure with a metallic film and to provide the metallic film with an opening as a spatial filter.

However, in the case of the laser device related to this report, the aperture of the current injection path is as small as 5.5 micrometers at maximum, thereby turning into a problem of causing an increase in operating voltage of the laser device.

Incidentally, the aperture of the current injection path of the semiconductor laser device is set to 5.5 micrometers presumably because this laser device allows the lateral lasing mode to be controlled mainly by the current injection path.

### SUMMARY

An object of the present invention is to provide a surface emitting semiconductor laser device which can control the lateral lasing mode and which can lase at a low operating voltage without a reduction in the aperture diameter of the current injection path and a need for accurate control.

To achieve the aforementioned object, there is provided a surface emitting semiconductor laser device, which is provided with a layered structure of semiconductor materials including an upper reflector layered structure, a lower reflector layered structure, and an active layer interposed therebetween, all formed on a substrate, with an upper electrical contact and a laser light emission window both being provided on an upper surface of the upper reflector layered structure. The surface emitting semiconductor laser device according to the present invention is characterized in that a current injection path having an aperture diameter greater than 10 micrometers is formed in close proximity to said active layer.

According to the present invention, the aperture diameter of the current injection path is as sufficiently large as 10 micrometers, thereby achieving lasing at a low operating voltage. In addition, the lateral lasing mode of the laser device can be controlled for the following reasons.

The present inventors have recognized that not only the aperture diameter of the current injection path of the laser device but also the aperture diameter of the emission window are closely related to the lateral lasing mode of the laser light generated in the active layer. Based on this recognition, the inventors fabricated laser devices having a laser light emission window of various aperture diameters to measure the properties of these laser devices. Consequently, it was concluded that lasing was made possible in a desired lateral mode by controlling the aperture diameter of the laser light emission window to a desired value.

The present invention was developed in accordance with the aforementioned findings. Lasing was achieved in a desired lateral lasing mode by controlling the aperture diameter of the emission window preferably with the upper electrical contact or a metallic film. This was carried out to allow the laser light emission window to have the desired aperture diameter or preferably an aperture diameter smaller than the aperture diameter of the current injection path. That is, the effective reflectivity of the upper reflector layered structure would be made higher immediately underneath the upper electrical contact or the metallic film. However, since the upper electrical contact or the metallic film transmits no light therethrough, lasing is made possible only at the aforementioned portion.

That is, the prior art mainly employed a current confinement layer as control means for achieving lasing in a desired lateral mode. In the prior art, an increase in aperture diameter of the current injection path to reduce the operating voltage of the laser device would make it impossible to control lateral modes (particularly, the fundamental lateral mode). However, the present invention mainly employs the laser light emission window as means for controlling lateral modes, thereby making it unnecessary to control the aperture diameter of the current injection path with accuracy in order to control lateral lasing modes.

In the present invention, part of the upper electrical contact is preferably coated with a metallic film. For example, the upper electrical contact is formed into an annulus-ring shape in plan configuration. At least part of the metallic film extends to close proximity to the inner peripheral rim of the upper electrical contact or to an inner portion thereof. Consequently, it is made possible to define the aperture diameter of the laser light emission window, for example, to a desired aperture diameter smaller than that of the current injection path by means of the upper electrical contact or the metallic film.

In fabrication of laser devices, it is comparatively easy to control the formation of the upper electrical contact or the metallic film on the outer surface of the laser device. Moreover, requirements for oxidation to control the aperture diameter of the current injection path are eased, thus facilitating the fabrication of the laser device as a whole. Consequently, this allows the laser device to be fabricated at an improved yield, leading to a reduction in cost of fabrication. In addition, this allows the laser device to be made uniform in property and to be designed with a higher degree of flexibility.

In the aforementioned preferred embodiment, the aperture diameter of said laser light emission window is made smaller than that of the current injection path. This makes it possible to make the aperture diameter of the current injection path comparatively large, thereby preventing an increase in resistance of the laser device as well as an increase in operating voltage thereof. Furthermore, lasing in higher order lateral modes is suppressed, preventing an increase in spectrum width of the laser light and in width of the radiation beam. Therefore, a laser device is provided which lases in a fundamental lateral mode at a low operating voltage. Furthermore, since the spectrum width of the laser light and the width of the radiation beam can be made narrower, a laser device is provided which facilitates optical coupling to an optical fiber and is useful as a light source for use in high-speed optical data transmission systems.

The metallic film preferably functions as an electrical contact lead pad. For this purpose, for example, the metallic film is formed around the upper electrical contact. The preferred embodiment provides a simplified arrangement of the electrical contact lead for the laser device.

### BRIEF DESCRIPTION OF THE DRAWINGS

FIG. 1 is a cross-sectional view illustrating a surface emitting semiconductor laser device according to an embodiment of the present invention,

FIG. 2 is a cross-sectional view of the laser device of FIG. 1 in its fabrication process with an SiNx film and a resist mask, both being formed on the layered structure formed on the substrate,

FIG. 3 is a cross-sectional view of a laser device in its fabrication process with a cylindrical structure being formed on the substrate,

FIG. 4 is a cross-sectional view of a laser device in its fabrication process with the cylindrical structure of FIG. 3 having been oxidized,

FIG. 5 is a cross-sectional view of a laser device in its fabrication process with the construction of FIG. 4 being provided with an upper electrical contact and a metallic film pad,

FIG. 6 is a graphical representation of the current—voltage and the current—optical output properties of a laser device according to an embodiment of the present invention,

FIG. 7 is a lasing spectrum of a laser device according to an embodiment of the present invention,

FIG. 8 is a far field pattern of the radiation emitted from a laser device according to an embodiment of the present invention,

FIG. 9 is a lasing spectrum of a laser device according to a comparative example,

FIG. 10 is a far field pattern of the radiation emitted from a laser device according to a comparative example, and

FIG. 11 is a cross-sectional view of a prior-art surface emitting semiconductor laser device A.

### DETAILED DESCRIPTION

A surface emitting semiconductor laser device according to an embodiment of the present invention will be explained below with reference to the drawings.

As shown in FIG. 1, a surface emitting semiconductor laser device B according to this embodiment is the same in basic construction as the prior-art laser device A shown in FIG. 11. That is, the laser device B has a layered structure formed on the substrate 1. The layered structure includes the lower reflector layered structure 2, the lower cladding layer 3a, the light-emitting layer 4, the upper cladding layer 3b, the upper reflector layered structure 5, and the GaAs layer 6. The lowermost layer 3c of the upper cladding layer 3b comprises the insulated region 3d and the current injection path 3e.

However, the laser device B according to this embodiment is different from the prior-art laser device A in the construction around the laser light emission window. That is, as shown in FIG. 11, the metallic film 9 of the laser device A extends in close proximity to the inner peripheral rim of the upper electrical contact 7a which is annular in plan configuration. Moreover, the laser light emission window (the center portion of the GaAs layer 6) 6a is defined by the inner peripheral rim of the upper electrical contact 7a. The aperture diameter of the emission window 6a is made equal to the inner diameter of the upper electrical contact 7a. In contrast, the metallic film 9 of the laser device B extends beyond the inner peripheral rim of the upper electrical contact 7a, which is annular in plan configuration, to an inner portion of the upper electrical contact 7a. Thus, a peripheral rim portion 6c of the emission window 6a of the prior-art laser device A is coated with the metallic film 9. That is, the peripheral rim of the upper opening of the metallic film 9 defines the emission window 6A. The aperture diameter of the emission window 6A is equal to the diameter of the upper opening of the metallic film 9 and smaller than the aperture diameter of the emission window 6a of the laser device A. Incidentally, the upper and inner peripheral surfaces of the upper electrical contact 7a are tightly coated with the metallic film 9, which in turn functions as an electrical contact lead pad. In addition, the laser device B holds for D₁>D₀ with D₁ being greater than 10 micrometers, where D₀ is the aperture diameter of the emission window 6A and D₁ is the aperture diameter of the current injection path 3e.

With the aforementioned relationship between D₁ and D₀, a voltage is applied between the upper electrical contact 7a and the lower electrical contact 7b to operate the laser device B. The effective reflectivity of the portion located immediately underneath the metallic film 9 of the upper reflector layered structure 5 is thereby increased. However, since the metallic film 9 transmits no light, lasing will take place only at a portion immediately underneath the metallic film 9. That is, formation of the metallic film 9 around the upper electrical contact 7a is controlled so that the relationship D₁>D₀ is held, thereby making it possible to control the lateral lasing mode.

Furthermore, the laser device B has the aperture diameter D₁ of the current injection path being made larger than 10 micrometers. This allows the control condition of the oxidization width of the AlAs layer 3c for controlling the aperture diameter D₁ to be more eased and thus facilitates fabrication of the laser device B.

### EXAMPLE

(1) Fabrication of Laser Device

The laser device shown in FIG. 1 was fabricated in the following manner. The lasing frequency of the laser device was designed to be 850 nm.

The lower reflector layered structure 2 comprising 30.5 pairs of multi-layered films was formed on the substrate 1 of n-type GaAs by the MOCVD method. The multi-layered films comprise alternating thin layers of n-type Al_{0.2}Ga_{0.8}As of thickness 40 nm and n-type Al_{0.9}Ga_{0.1}As of thickness 50 nm with composition gradient layers of thickness 20 nm being interposed between the heterointerfaces. Then, the lower cladding layer 3a (of thickness 90 nm) of non-doped Al_{0.3}Ga_{0.7}As, the light-emitting layer 4, and the upper cladding layer 3b (of thickness 90 nm) of non-doped Al_{0.3}Ga_{0.7}As were deposited in that order on the lower reflector layered structure 2. Here, the light-emitting layer 4 has a quantum well structure comprising a quantum well of three layers of GaAs (each layer having a thickness of 7 nm) and a barrier stack of four layers of Al_{0.2}Ga_{0.8}As (each layer having a thickness of 10 nm). Furthermore, the upper reflector layered structure 5 comprising 25 pairs of multi-layered films was formed on the upper cladding layer 3b. The multi-layered films comprise alternating thin films of p-type Al_{0.2}Ga_{0.8}As of thickness 40 nm and p-type Al_{0.9}Ga_{0.1}As of thickness 50 nm with composition gradient layers of thickness 20 nm being interposed between the heterointerfaces.

Then, the p-type GaAs layer 6 was deposited on the layer of p-type Al_{0.2}Ga_{0.8}As, that is, the uppermost layer of the upper reflector layered structure 5.

Incidentally, the lowermost layer 3c of the upper reflector layered structure was formed not of Al_{0.9}Ga_{0.1}As but of p-type AlAs of thickness 50 nm. Then, this lowermost layer 3c will be converted into a current confinement structure by the processing to be described later.

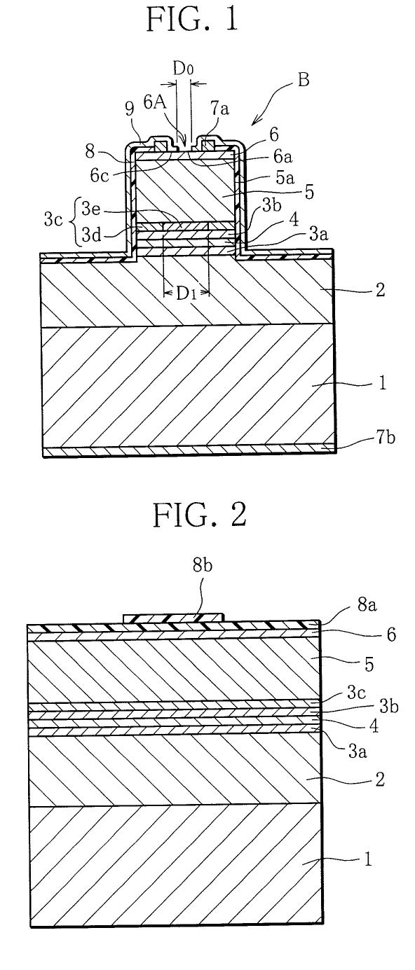

Subsequently, an SiNx film 8a was deposited by the plasma CVD method on the surface of the p-type GaAs layer 6. Thereafter, a circular resist mask 8b of diameter approximately 45 micrometers was formed on the SiNx film 8a by photolithography employing an ordinary photoresist (FIG. 2).

Then, the SiNx film 8a was removed except for the SiNx film located immediately beneath the resist mask 8b by RIE (Reactive Ion Etching) with CF₄. Next, all the resist mask 8b was removed to obtain the SiNx film 8a having a circular shape in plan configuration, allowing the surface of the portion of GaAs layer 6 to be exposed which is annular in plan configuration and not located immediately beneath the SiNx film 8a.

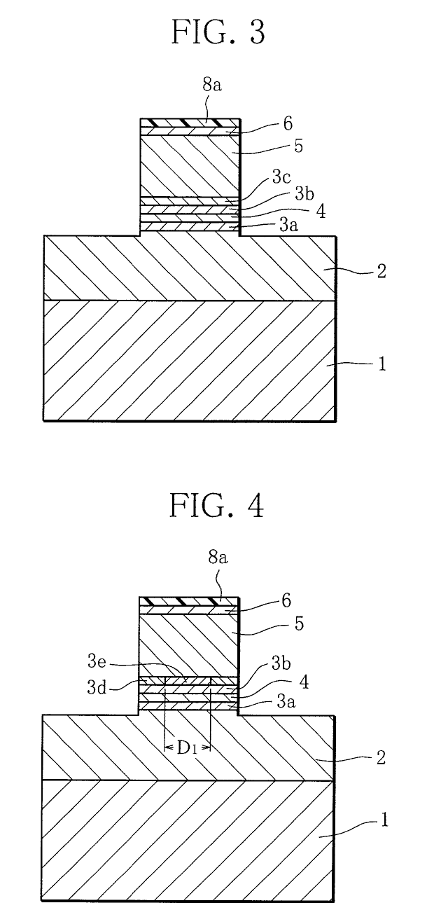

Then, the SiNx film 8a was employed as a mask and an etchant was used which was composed of a mixture of phosphoric acid, hydrogen peroxide, and water in order to perform etching. The etching was performed on the portion of the layered structure from the GaAs layer 6 to the vicinity of the upper surface of the lower reflector layered structure 2, thereby forming a pillar-shaped structure (FIG. 3).

Then, the layered structure was heated for about 25 minutes at a temperature of 400° C. in a water vapor to selectively oxidize, in an annular shape, only the outside of the lowermost layer 3c of p-type AlAs of the upper reflector layered structure 5. Thus, the current injection path 3e of diameter D₁ approximately 15 micrometers was formed at the center portion of the layer 3c (FIG. 4).

Subsequently, the SiNx film 8a was completely removed by RIE and thereafter the outer surface of the pillar-shaped structure and the upper surface of the lower reflector layered structure 2 were coated with the SiNx film 8 by the plasma CVD method. Then, the center portion of the SiNz film 8 formed on the upper surface of the GaAs layer 6 approximately 45 micrometers in diameter was removed to form into a circular portion of 25 micrometers in diameter, allowing the surface of the GaAs layer 6 to be exposed.

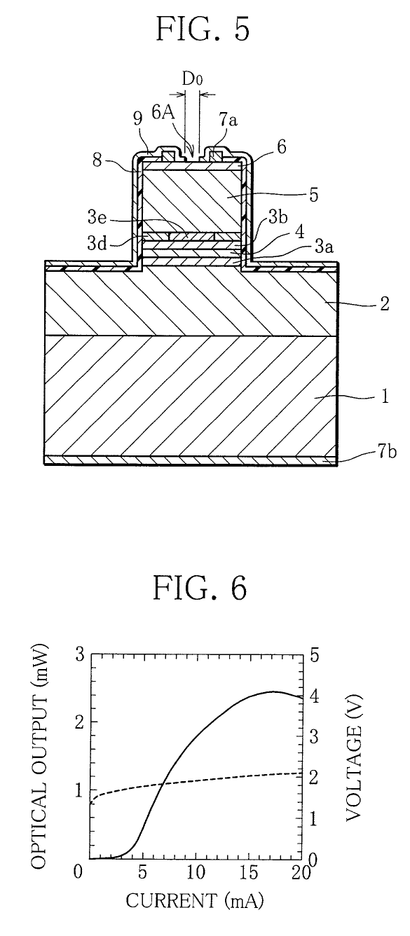

Then, on the surface of the GaAs layer 6, the upper electrical contact 7a annular in shape was formed which has an outer diameter of 25 micrometers and an inner diameter of 15 micrometers. Moreover, on the surface of the pillar-shaped structure, the metallic film 9 was formed which functioned as an electrical contact lead pad. At this time, a metallic film was deposited on the inner side of the upper electrical contact 7a to form an opening having diameter D₀ of 10 micrometers as the emission window 6A (FIG. 5).

Then, the reverse surface of the substrate 1 was polished to have a total thickness of about 100 micrometers, and thereafter AuGeNi/Au was deposited on the polished surface by evaporation to form the lower electrical contact 7b.

(2) Properties of Laser Device

The solid line in FIG. 6 represents the current—optical output property of the laser device, and the broken line of FIG. 6 represents the current—voltage property thereof.

As can be seen in FIG. 6, the laser device starts lasing at a threshold current of 4 mA and the optical output will not become saturated until the injection current increases up to about 15 mA. In addition, the operating voltage is 2.0V at the injection current of 15 mA, which is sufficiently low.

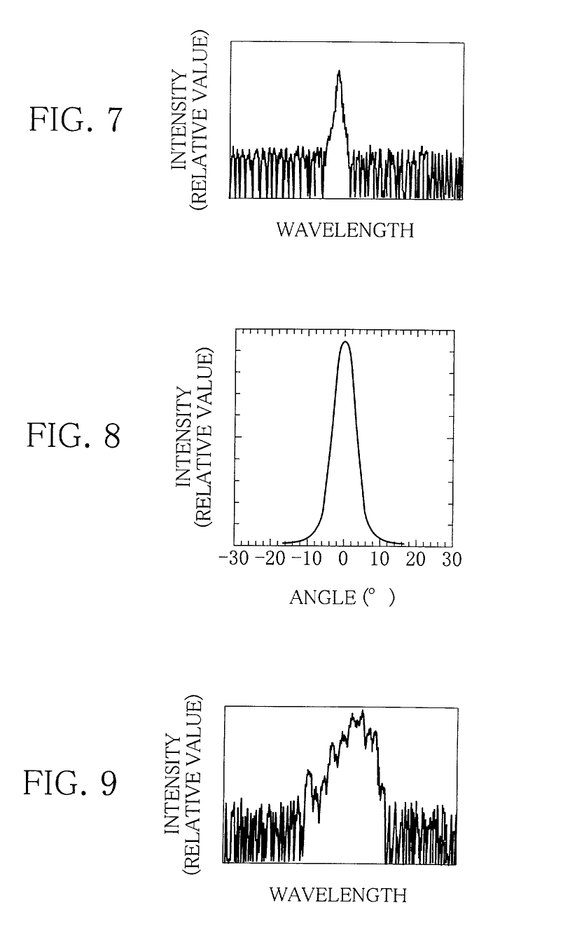

On the other hand, a lasing spectrum of the laser device is shown in FIG. 7 and a far field pattern of the radiation thereof is shown in FIG. 8, respectively.

As can be seen in FIGS. 7 and 8, in this laser device, lasing takes place at a single frequency in spite of the aperture diameter of the current injection path 3e being equal to 15 micrometers, and the far field pattern of the radiation has a single peak. This shows that the laser device lases in a single lateral mode.

Incidentally, the same properties as those of the aforementioned laser device were obtained in the following laser devices. The laser devices had the aperture diameter (D₁) of the current injection path 3e and the aperture diameter (D₀) of the emission window 6A, which were set to 20 micrometers and 15 micrometers, respectively. In addition, the laser devices had the aperture diameter (D₁) of the current injection path 3e and the aperture diameter (D₀) of the emission window 6A, which were set to 10 micrometers and 7 micrometers, respectively.

### COMPARATIVE EXAMPLE

To be compared with the laser device according to the present invention, a laser device having the same layered structure as a whole with D₁=10 micrometers and D₀=15 micrometers was fabricated (corresponding to the laser device A shown in FIG. 11).

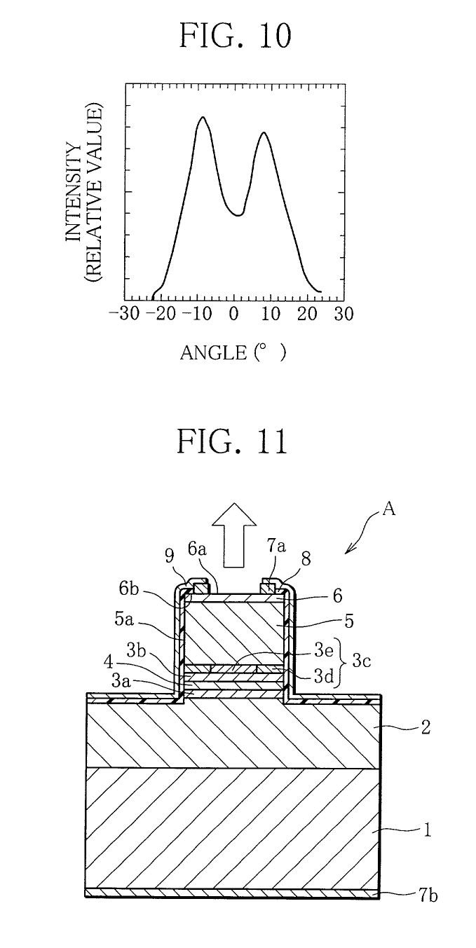

The lasing spectrum of the laser device A is shown in FIG. 9, and the far field pattern of the radiation thereof is shown in FIG. 10, respectively.

The laser device A holds for D₁<D₀ and lases in multi modes with a far field pattern of the radiation thereof showing dual peaks.

Based on this, it can be found that the laser device should hold for D₁>D₀ to implement a single lateral lasing.

In addition, with D₁ being 10 micrometers, the laser device A was provided with an operating voltage of 2.5V at an injection current of 15 mA. Therefore, it can be found that D₁ should be made greater than 10 micrometers to implement the operation at a low voltage.

The laser device according to the present invention has been explained so far, however, the present invention is not limited to those described above but may be modified in various manners.

For example, in the example, the metallic film is allowed to extend to the inner portion of the annular upper electrical contact to define the aperture diameter of the laser light emission window by the metallic film. However, like the laser device shown in FIG. 11, the metallic film may be allowed to extend to close proximity to the inner peripheral rim of the upper electrical contact to define the aperture diameter of the laser light emission window by the inner peripheral rim of the upper electrical contact. However, unlike the case of FIG. 11, the inner diameter of the upper electrical contact (that is, the aperture diameter of the laser light emission window) is made smaller than the aperture diameter of the current injection path.

Furthermore, in the example, the laser device lasing at a wavelength of 850 nm has been explained, however, the laser device according to the present invention will behave in the same manner at any other wavelengths. In addition, the example employs the n-type substrate. However, a p-type substrate may be employed as the substrate. In this case, the lower reflector layered structure may be formed of a p-type semiconductor material and the upper reflector layered structure may be formed of an n-type semiconductor material.

What is claimed is:

1. A surface emitting semiconductor laser exhibiting fundamental lateral mode lasing comprising:
a light generating active layer, and
a partially oxidized current confinement layer proximate to said active layer, wherein said current confinement layer defines a current injection path having an aperture of greater than 10 micrometers in diameter.

2. The laser of claim 1, wherein said laser comprises a laser light emission window having a diameter which is less than the diameter of said current injection path.

3. The laser of claim 2, wherein said current injection path has a diameter of approximately 15 micrometers, and wherein said laser light emission window has a diameter of approximately 10 micrometers.

4. A surface emitting semiconductor laser comprising:
a substrate;
an upper reflector and a lower reflector with an active layer interposed therebetween, all formed on an upper surface of said substrate;
a current injection path having a diameter greater than 10 micrometers in close proximity to said active layer;
a laser light emission window on an upper surface of said upper reflector;
an upper electrical contact on said upper surface of said upper reflector; and
a lower electrical contact on a lower surface of said substrate.

5. The surface emitting semiconductor laser device of claim 4, wherein said laser light emission window has a diameter which is smaller than the diameter of said current injection path.

6. The surface emitting semiconductor laser device of claim 4, wherein part of said upper electrical contact is coated with a metallic film.

7. The surface emitting semiconductor laser device of claim 4, wherein said upper electrical contact is formed to be annular in shape, and at least part of said metallic film extends to an inner portion of said upper electrical contact to define said laser light emission window.

8. A semiconductor laser comprising:
an optically active layer;
a partially oxidized layer proximate to said optically active layer and forming a current injection path having a first diameter;
a laser light emission window having a second diameter; and
a pair of electrodes positioned to direct current through said current injection path and said optically active layer, wherein said first diameter and said second diameter are configured such that the laser operates in a fundamental lateral mode and has a saturated optical output with less than 2.5 V applied to said electrodes.

9. The semiconductor laser of claim 8, wherein said optical output is saturated at about 2.0 V or less.

10. A method of producing laser light comprising:
injecting current through a current injection path having a diameter of greater than 10 micrometers and into an optically active semiconductor layer; and
emitting light generated in said optically active semiconductor layer through an emission window that has a diameter which is less than the diameter of said current injection path.

11. The method of claim 10, wherein said injecting comprises applying an electrical signal between a first electrical contact formed on one side of said current injection path and a second electrical contact formed on the other side of said current injection path.

12. A method of making a surface emitting semiconductor laser comprising the step of controlling both the diameter of a current injection path and the diameter of a laser light emission window such that (1) the diameter of the current injection path is greater than 10 micrometers, (2) the diameter of the laser light emission window is smaller than the diameter of the current injection path, and (3) the laser exhibits lasing in the fundamental lateral mode.

13. A method of forming a surface emitting semiconductor laser device comprising:
depositing a first layered reflector onto a substrate;
depositing a light-emitting layer over said first layered reflector;
depositing a selectively oxidizing layer near said light-emitting layer;
depositing a second layered reflector over said light-emitting layer;
forming a pillar shaped structure affixed to the substrate by etching away a portion of the deposited layers;
selectively oxidizing radially inward from its outermost edge so as to form a current injection path of diameter D₁ greater than 10 micrometers through the non-oxidized central portion of the selectively oxidizing layer;
depositing an annular shaped upper electrical contact on the second layered reflector;
forming a laser light emission window on the second layered reflector, said laser light emission window having a diameter of less than D₁.

14. The method of claim 13, wherein forming said laser light emission window comprises depositing a metallic film extending over at least part of the upper electrical contact and radially inward from the inside of the upper electrical contact to form a circular opening having a diameter of less than D₁.

15. The method of claim 13, wherein said oxidizing comprises heating the pillar shaped structure to a temperature of more than 350 degrees C. for about 25 minutes in water vapor.

16. A method of controlling the lasing mode and electrical impedance of a semiconductor laser, said semiconductor laser comprising an active layer, a current injection path through said active layer, and a laser light emission window, said method comprising controlling both the diameter of the current injection path and the diameter of the laser light emission window such that the diameter of the current injection path is greater than 10 micrometers and the diameter of the laser light emission window is smaller than the diameter of the current injection path.

17. An optical data transmission system comprising:
a vertical cavity surface emitting laser comprising:
a light generating active layer;
a partially oxidized current confinement layer proximate to said active layer, wherein said current confinement layer defines a current injection path having an aperture of greater than 10 micrometers in diameter; and
a laser light emission window; said system further comprising:
a single mode optical fiber coupled to said laser light emission window.

18. The system of claim 17, wherein said laser light emission window has a diameter which is less than the diameter of said current injection path.

19. An optical data transmission system comprising:
a vertical cavity surface emitting laser comprising:
a light generating active layer;
a partially oxidized current confinement layer proximate to said active layer, wherein said current confinement layer defines a current injection path having an aperture of greater than 10 micrometers in diameter; and
a laser light emission window; said system further comprising:
a free space optical transmission path coupled to said laser light emission window.

20. The system of claim 19, wherein said laser light emission window has a diameter which is less than the diameter of said current injection path.
